(19) United States
(12) Patent Application Publication
(10) Pub. No.: US 2022/0359162 A1
(43) Pub. Date: Nov. 10, 2022

(54) PLASMA PROCESSING APPARATUS

(71) Applicant: Hitachi High-Tech Corporation, Minato-ku, Tokyo (JP)

(72) Inventors: Hitoshi Tamura, Tokyo (JP); Norihiko Ikeda, Tokyo (JP)

(21) Appl. No.: 17/274,947

(22) PCT Filed: Jan. 27, 2020
(86) PCT No.: PCT/JP2020/002737

§ 371 Date: Mar. 10, 2021

(51) Int. Cl. H01J 37/32; H01P 3/16

(52) U.S. Cl. CPC H01J 37/32311; H01J 37/32678; H01J 37/32229; H01P 3/16; H01J 2237/334

(57) ABSTRACT

In order to provide a plasma processing apparatus capable of easily controlling a plasma density distribution on a processing target substrate, a plasma processing apparatus includes: a microwave generating source; a waveguide path including waveguides that transmit a microwave generated by the microwave generating source to a processing chamber; the processing chamber that includes therein a placing table for placing the processing target substrate and is connected to the waveguide path; a gas introduction unit that introduces gas into the processing chamber; and an exhaust unit that discharges the gas introduced into the processing chamber to the outside of the processing chamber, in which a portion of the waveguide path connected to the processing chamber includes a plurality of waveguides formed coaxially.

### TECHNICAL FIELD

The present invention relates to a plasma processing apparatus that generates plasma by an electromagnetic wave.

### BACKGROUND ART

A plasma processing apparatus is used in production of semiconductor integrated circuit elements. In a plasma processing apparatus that generates plasma by an electromagnetic wave, an apparatus in which a static magnetic field is applied to a plasma processing chamber is widely used. This is because the static magnetic field has advantages that loss of the plasma can be prevented and plasma distribution can also be controlled. Furthermore, by using an interaction between the electromagnetic wave and the static magnetic field, there is an effect that the plasma can be generated even under an operating condition where the plasma is usually difficult to be generated.

In particular, it is known that when a microwave is used as the electromagnetic wave for plasma generation and a static magnetic field that matches a period of electron cyclotron motion with a frequency of the microwave is used, an electron cyclotron resonance (hereinafter, referred to as ECR) phenomenon occurs. Since the plasma is mainly generated in a region where ECR occurs, in addition to that a plasma generation region can be controlled by adjusting distribution of the static magnetic field, there is also an effect that conditions under which the plasma can be generated can be widely ensured by the ECR phenomenon.

An RF bias technique is used to speed up plasma processing and improve processing quality by applying a radio frequency to a processing target substrate under the plasma processing and attracting ions in the plasma onto a surface of the processing target substrate. For example, in the case of plasma etching processing, since the ions are vertically incident on a surface to be processed of the processing target substrate, anisotropic processing in which etching proceeds only in a vertical direction of the processing target substrate is achieved.

Patent Literature 1 describes a plasma processing apparatus including: a plasma-generating electromagnetic wave introduction path that is installed concentrically with a central axis of a processing chamber; a branch circuit that distributes an electromagnetic wave to a plurality of output ports; and a ring-shaped cavity resonator that is connected to the output ports of the branch circuit and installed concentrically with the plasma-generating electromagnetic wave introduction path, in which the plasma-generating electromagnetic wave introduction path includes a circular waveguide, so that a traveling wave is excited in the ring-shaped cavity resonator. Thereby, it is possible to prevent a spatial variation in plasma density caused by a standing wave and to perform uniform plasma processing.

When the microwave is used as power for plasma generation, a waveguide is used to transmit microwave power, but it is generally known that when a size of the waveguide is smaller than a wavelength of the microwave, the microwave cannot be transmitted, which is called a cutoff. Non-Patent Literature 1 describes a relationship in a case of a circular waveguide between a size of the circular waveguide and a cutoff frequency.

### CITATION LIST

### Patent Literature

PTL 1: JP-A-2012-190899

### Non-Patent Literature

Non-Patent Literature 1: Masamitsu Nakajima, Microwave Engineering, Morikita Publishing Co., Ltd.

### SUMMARY OF INVENTION

### Technical Problem

In general, plasma is often lost on a wall surface of a plasma processing chamber, and has a tendency that a density becomes low near the wall surface and the density becomes high near a center away from the wall surface. Non-uniform processing caused by such non-uniformity of plasma density distribution may cause problems. In a plasma processing apparatus using a static magnetic field, the density may become high near the center of the plasma processing chamber depending on plasma generation conditions. Accordingly, the plasma density on a processing target substrate tends to easily become a convex distribution, and uniformity of plasma processing may be a problem.

The plasma has a property of easily diffusing in a direction along a magnetic force line but being prevented from diffusion in a direction perpendicular to the magnetic force line. Furthermore, by adjusting distribution of the static magnetic field, it is possible to adjust a position of an ECR surface or the like to control a plasma generation region. Distribution of the plasma can be adjusted by adjusting the distribution of the static magnetic field in this way.

However, it may not be possible to obtain a desired adjustment range only by a unit that adjusts the plasma density distribution by the static magnetic field, and thus an additional unit for adjustment is further desired.

For example, in the case of etching processing, a film thickness obtained by processing may be, for example, thick at a center and thin at an outer peripheral side of the processing target substrate, or conversely thin at the center and thick at the outer peripheral side, depending on characteristics of film forming apparatuses. It may be desired to correct by the etching processing the non-uniformity caused by these film forming apparatuses so as to perform entirely uniform processing. It may be desired to adjust the plasma density distribution on the processing target substrate to a desired distribution in this way.

Generally, if an etching rate is uniform, a reaction product is uniformly produced and released from each part of the processing target substrate. As a result, a density of the reaction product is high in a central portion and is low in an outer peripheral portion of the processing target substrate. When the reaction product reattaches to the processing target substrate, etching is inhibited and the etching rate decreases. A probability that the reaction product reattaches to the processing target substrate is affected by many parameters such as temperature of the processing target substrate, a pressure in the processing chamber, and a surface condition of the processing target substrate. Therefore, in order to obtain uniform etching processing in the surface of the processing target substrate, it may be necessary to adjust the plasma density distribution on the processing target substrate to a center higher or outer higher distribution.

As a configuration of the plasma processing apparatus that enables easy control of the plasma density distribution on the processing target substrate as shown above, an electromagnetic field in the ring-shaped cavity resonator forms a standing wave in Patent Literature 1. For example, when a standing wave of an electric field is formed, there are antinodes having a strong electric field intensity and nodes having a weak electric field intensity. Positions of these antinodes and nodes are fixed, and the strong and weak electric field intensities corresponding to electric field intensity antinodes and nodes in the cavity resonator may also occur in the plasma processing chamber.

Due to the strong and weak electric field intensities, the plasma generated in the processing chamber may also become non-uniform. Due to the non-uniformity, problems may occur such as increasing local scrape-off, due to the plasma, of a dielectric window portion that allows the microwave to pass through while keeping a vacuum processing chamber airtight, and adverse effect on the uniformity of the plasma processing applied to the processing target substrate.

In order to solve the problems of the related art as described above, the invention provides a plasma processing apparatus capable of easily controlling a plasma density distribution on a processing target substrate.

### Solution to Problem

In order to solve the above problems, in the invention, a plasma processing apparatus includes: a processing chamber in which a sample is subjected to plasma-processing; a radio frequency power source configured to supply, via a waveguide path, radio frequency power of a microwave for generating plasma; a magnetic field forming mechanism configured to form a magnetic field inside the processing chamber; and a cutoff frequency control mechanism configured to control a cutoff frequency. The waveguide path includes a circular waveguide and a coaxial waveguide disposed outside the circular waveguide and disposed coaxially with the circular waveguide. The cutoff frequency control mechanism is configured to control a cutoff frequency of the circular waveguide.

### Advantageous Effect

According to the invention, it is possible to provide a plasma processing apparatus capable of easily controlling plasma density distribution on a processing target substrate.

### BRIEF DESCRIPTION OF DRAWINGS

FIG. 1 is a side sectional view of a microwave plasma etching apparatus for explaining a principle of the microwave plasma etching apparatus according to the invention.

FIG. 2 is a side sectional view of a microwave plasma etching apparatus according to an embodiment of the invention.

FIG. 3 is a cross-sectional view taken along a line A-A in FIG. 2 of the microwave plasma etching apparatus according to the embodiment of the invention.

FIG. 4 is a cross-sectional view taken along a line B-B in FIG. 2 of the microwave plasma etching apparatus according to the embodiment of the invention.

FIG. 5 is a cross-sectional view of the vicinity of a circularly polarized wave generator of the microwave plasma etching apparatus according to the embodiment of the invention.

FIG. 6 is a side sectional view of a dielectric component of the microwave plasma etching apparatus according to the embodiment of the invention.

FIG. 7 is a side sectional view of a dielectric component of the microwave plasma etching apparatus according to the embodiment of the invention.

### DESCRIPTION OF EMBODIMENTS

The invention provides a plasma processing apparatus capable of performing high-quality plasma processing. The invention relates to a plasma processing apparatus in which distribution of plasma generated in a processing chamber can be controlled by specifically adjusting distribution of microwave power.

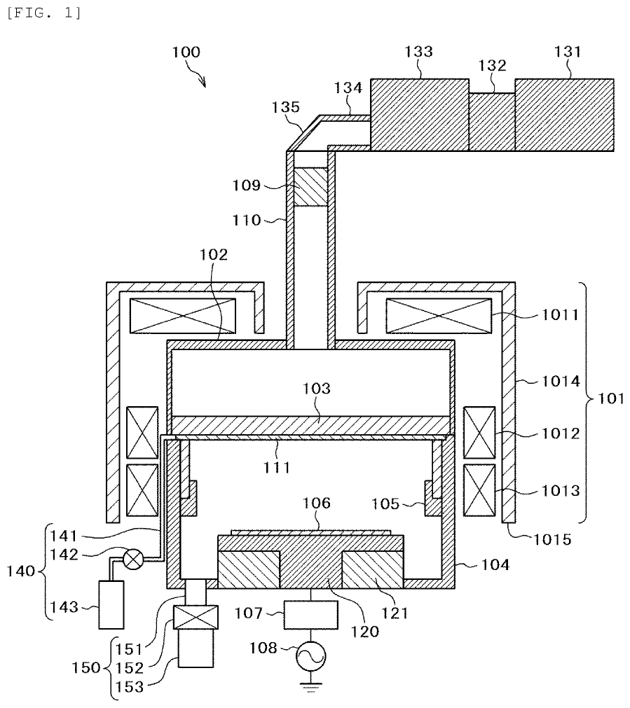

In order to explain a principle of the invention, FIG. 1 shows an etching apparatus 100 as an example of a plasma processing apparatus using ECR. The etching apparatus 100 for explaining the principle of the invention includes a substantially cylindrical plasma processing chamber 104. An inside of the plasma processing chamber 104 is provided with a substrate electrode 120 on which a processing target substrate 106 is placed, and a dielectric block 121 that electrically insulates the plasma processing chamber 104 from the substrate electrode 120. The inside of the plasma processing chamber 104 is further provided with a ground electrode 105 that operates as a ground for RF bias.

On the other hand, a cavity portion 102 is formed above the plasma processing chamber 104, and a microwave introduction window 103 and a gas dispersion plate 111 are provided between the plasma processing chamber 104 and the cavity portion 102. Processing gas, inert gas, or the like is supplied between the microwave introduction window 103 and the gas dispersion plate 111 from a gas supply unit 140, and the gas is supplied from a large number of fine holes (not shown) in the gas dispersion plate 111 to the inside of the plasma processing chamber 104.

The gas supply unit 140 includes a gas cylinder 143, a switching valve 142 that switches between supply and stop of the gas, and a gas supply pipe 141 that connects the switching valve 142 with the plasma processing chamber 104.

The inside of the plasma processing chamber 104 is evacuated to vacuum by an exhaust system 150. The exhaust system 150 includes an exhaust pipe 151 connected to the plasma processing chamber 104, a butterfly valve 152 that can be opened and closed, and a vacuum pump 153. As a result, the gas supplied from the gas supply unit 140 to the inside of the plasma processing chamber 104 is also exhausted from the plasma processing chamber 104 by the exhaust system 150.

An electromagnet 101 is provided around the plasma processing chamber 104. The electromagnet 101 includes an upper coil 1011 and lower coils 1012 and 1013, and a yoke 1014 is provided on outer peripheries of the upper coil 1011 and the lower coils 1012 and 1013 to prevent a magnetic field from leaking to the outside and to efficiently concentrate the magnetic field in the plasma processing chamber.

A circular waveguide 110 is connected to the cavity portion 102 along a central axis, and the circular waveguide 110 is connected to a rectangular waveguide 134 via a circular-rectangular converter 135. A microwave generating source 131, an isolator 132, and an automatic matching box 133 are connected to the rectangular waveguide 134.

In the etching apparatus 100 for explaining the principle of the invention, which has the above-described configuration, the electromagnet 101 provided around the substantially cylindrical plasma processing chamber 104 can apply a static magnetic field for causing ECR to the inside of the plasma processing chamber 104. Distribution of the static magnetic field in the plasma processing chamber 104 can be controlled by adjusting an intensity of the magnetic field generated by the multi-stage coils 1011, 1012, and 1013 constituting the electromagnet 101.

A microwave generated by the microwave generating source 131 and passed through the isolator 132 and the automatic matching box 133 is input, by the circular waveguide 110 provided along the central axis of the plasma processing chamber 104, into the plasma processing chamber 104 from a surface of the plasma processing chamber 104 facing the processing target substrate 106 placed on the substrate electrode 120. A magnetron having an oscillation frequency of 2.45 GHz is used as the microwave generating source 131.

The automatic matching box 133 connected to an output side of the microwave generating source 131 is used for preventing a reflected wave due to impedance mismatch with the isolator 132 for protecting the generating source. The microwave generating source 131 to the automatic matching box 133 are connected by using the rectangular waveguide 134. The circular-rectangular converter 135 is used for connection with the circular waveguide 110.

The circular waveguide 110 operates in a TE11 mode as a lowest-order mode and is set to a diameter that allows only the lowest-order mode to propagate, so that the occurrence of a higher-order mode is prevented and the operation can be stabilized. A circularly polarized wave generator 109 is provided in the circular waveguide 110 to perform circularly polarized wave processing on the microwave in the TE11 mode.

In the TE11 mode, an electromagnetic field changes in an azimuth direction with respect to the central axis of the circular waveguide, but the circularly polarized wave processing by the circularly polarized wave generator 109 has effects of smoothing the non-uniformity in the azimuth direction in one cycle of the microwave and ensuring axial symmetry. In addition, it is known that an electron cyclotron resonance phenomenon described later occurs efficiently when the microwave subjected to the circularly polarized wave processing is input to the plasma to which the static magnetic field is applied, which also has an effect of increasing an absorption efficiency of the microwave power into the plasma.

The microwave input from the circular waveguide 110 is shaped in distribution of the electromagnetic field in the cavity portion 102 and input into the plasma processing chamber 104 via the microwave introduction window 103 and the gas dispersion plate 111 provided on a processing chamber side thereof. The microwave introduction window 103 and the gas dispersion plate 111 often use quartz as a material that transmits the microwave and does not easily adversely affect the plasma processing. In addition, an inner surface of the plasma processing chamber 104 is often protected by an inner cylinder made of quartz or the like to prevent damage caused by the plasma.

A silicon substrate having a diameter of 300 mm is used as the processing target substrate 106. A radio frequency (RF) power source 108 is connected to the substrate electrode 120 on which the processing target substrate 106 is placed via an automatic matching box 107, and applies the above-mentioned RF bias. An RF power source 108 having a frequency of 400 kHz is used.

The gas, after exiting the gas supply unit 140 that supplies the processing gas, the inert gas, or the like to the inside of the plasma processing chamber 104, is supplied between the microwave introduction window 103 and the gas dispersion plate 111 in the plasma processing chamber 104 by the gas supply pipe 141 via the valve 142, and is supplied in a shower shape to the inside of the plasma processing chamber 104 through the fine holes (not shown) provided in the gas dispersion plate 111. Distribution of gas supply can be adjusted by arranging the holes in the gas dispersion plate 111.

In order to apply the above-mentioned RF bias technique, an impedance of a path from the processing target substrate 106 to the ground via the plasma is important. That is, it is known that a sheath formed between the processing target substrate 106 and the plasma has non-linear impedance, and thus, when an RF bias current flows through the sheath region, a DC potential of the processing target substrate 106 is lowered and ions in the plasma can be attracted. The ground electrode 105 is provided inside the plasma processing chamber 104 in order to allow the RF bias current to flow efficiently.

The static magnetic field generated by the electromagnet 101 is often set to be substantially parallel to an input direction of the microwave. This is because it is known that ECR generated by a microwave efficiently occurs due to a static magnetic field parallel to a traveling direction of the microwave. In the example of FIG. 1, the static magnetic field is applied in a direction along the central axis of the plasma processing chamber.

Propagation characteristics of microwave in magnetized plasma have been theoretically clarified to some extent, and it is known that a circularly polarized wave that propagates in a direction along a static magnetic field, which is called an R wave, can propagate in a plasma in a strong magnetic field region that exceeds the static magnetic field under an ECR condition regardless of a density of the plasma. It is also known that the microwave power is absorbed extremely efficiently by electrons at a location that satisfies the above-mentioned ECR condition. Therefore, in order to efficiently propagate the microwave power to the location that satisfies the ECR condition, the microwave is input from the strong magnetic field region and propagates in the plasma.

In the example shown in FIG. 1, a strong static magnetic field is set in the upper part of the plasma processing chamber 104, a weak static magnetic field is set in a lower part thereof, and a magnetic flux density satisfying the ECR condition (0.0875 Tesla when a frequency of the microwave is 2.45 GHz) is set in the middle thereof, and the microwave is input from an upper side. The setting is such that the static magnetic field, which is monotonically weakened from the upper side along a central axis of the electromagnet 101 (referred to as a divergent magnetic field), is easily generated. That is, the electromagnet 101 has a configuration in which a magnetomotive force of the upper coil 1011 is relatively larger than that of the lower coils 1012 and 1013 and thus is likely to generate a static magnetic field that is strong in the upper coil 1011 and is relatively weak in the lower coils 1012 and 1013.

The yoke 1014 is often provided on an outer periphery of the electromagnet 101 to prevent the magnetic field from leaking to the outside and to efficiently concentrate the magnetic field in the plasma processing chamber. The yoke 1014 is preferably made of a material having a high saturation magnetic flux density, and is often made of pure iron because of its low price and easy availability. In order to efficiently apply the static magnetic field into the plasma processing chamber 104, the yoke 1014 is disposed so as to cover the entire plasma processing chamber 104. A lower end 1015 of the yoke 1014 extends to the vicinity of a surface on which the processing target substrate 106 exists.

In contrast to the configuration for explaining the principle of the invention which is illustrated in FIG. 1, in the invention, a waveguide path for transmitting the microwave power is divided into a plurality of waveguide paths, microwave radiation units are respectively provided on processing chamber sides of the respective waveguide paths, and a unit for adjusting the power of the microwave propagating in the respective waveguide paths is further provided, so that distribution of a microwave electromagnetic field in the processing chamber is adjusted to control the distribution of the generated plasma.

All of these structures are concentrically disposed to prevent occurrence of non-axial symmetry in the microwave and the plasma. That is, the waveguide path for transmitting the microwave includes a combination of a circular waveguide and a coaxial waveguide having a central axis common with the central axis of the circular waveguide. The principle of the invention will be described below.

A phenomenon called a waveguide cutoff can be used to adjust the microwave power. It is generally known that when a size of the waveguide is smaller than a wavelength of the microwave, the microwave cannot be transmitted, which is called a cutoff. It is also known that by loading a dielectric having a large relative permittivity in the waveguide, a cutoff size can be reduced due to a wavelength shortening effect.

In the case of the circular waveguide, a fact is known as represented by a formula (Formula 1) as described in Non-Patent Literature 1.

k_{ca}=ρₘₙ′ [Formula 1]

k_{c}: cutoff wavenumber (rad/m)

a: radius of circular waveguide (m)

μₘₙ′: n-th root of r-direction differentiation

$$\frac{d}{dr} {J}_{m} ( r ) = 0$$

of m-order Bessel function Jₘ(r)

Furthermore, a cutoff wavenumber is given by a formula (Formula 2).

$${k}_{c} = \frac{2 π}{c} {f}_{c} c = \frac{1}{\sqrt{{ε}_{r}}} \frac{1}{\sqrt{{ε}_{0} {μ}_{0}}} \qquad [ Formual 2 ]$$

ε₀: permittivity of vacuum (=8.854×10⁻¹² F/m)

μ₀: magnetic permeability of vacuum (=1.257×10⁻⁶ H/m)

εᵣ: relative permittivity

f_{c}: cutoff frequency (Hz)

ρₘₙ′ corresponding to the TE11 mode of the circular waveguide is ρ₁₁′ =1.841.
At this time, given that the cutoff frequency is 2.45 GHz, and the relative permittivity is 1 assuming the case of air,

$$a = \frac{c}{2 π {f}_{c}} {ρ}_{mn}^{′} = 0.03585 ( m ) ;$$

and
given that the relative permittivity is 4 assuming the case of quartz,

$$a = \frac{c}{2 π {f}_{c}} {ρ}_{mn}^{′} = 0.01793 ( m ) .$$

That is, it can be seen that when a medium in the circular waveguide is air, a microwave of 2.45 GHz can be cut off if the radius is 35.9 mm or less, and when the medium is quartz, a microwave having 2.45 GHz can be transmitted if the radius is 17.9 mm or more.

From the above, when the frequency of the microwave is 2.45 GHz, by setting the radius of the waveguide to 17.9 mm or more and less than 35.9 mm, the microwave power can be cut off if the medium in the waveguide is air, and can be transmitted if quartz is loaded.

Furthermore, it is known that in a waveguide in a cutoff state, a microwave electric field decreases exponentially from an input end of a microwave. That is, a magnitude of the microwave leaking to an output end can be adjusted by adjusting a length of the waveguide in the cutoff state.

A microwave can be transmitted when a cylinder is coaxially loaded in a circular waveguide and a dielectric is loaded inside the cylinder, and can be cut off when the dielectric is not loaded. By enabling insertion and removal the dielectric, it is possible to perform adjustment so as to perform cutting off or enable transmission. Furthermore, an outside of the cylinder can be operated as the coaxial waveguide, and a division ratio of the microwave power can be controlled by dividing the microwave power into the inner circular waveguide and the outer coaxial waveguide and controlling transmission power of the inner circular waveguide.

Hereinafter, embodiments of the invention will be described in detail with reference to drawings. In all the drawings for explaining the present embodiment, those having the same function are denoted by the same reference numerals, and the repetitive description thereof will be omitted in principle.

However, the invention should not be construed as being limited to the description of the embodiments described below. Those skilled in the art will easily understand that specific configurations can be changed without departing from the spirit or scope of the invention.

### Embodiments

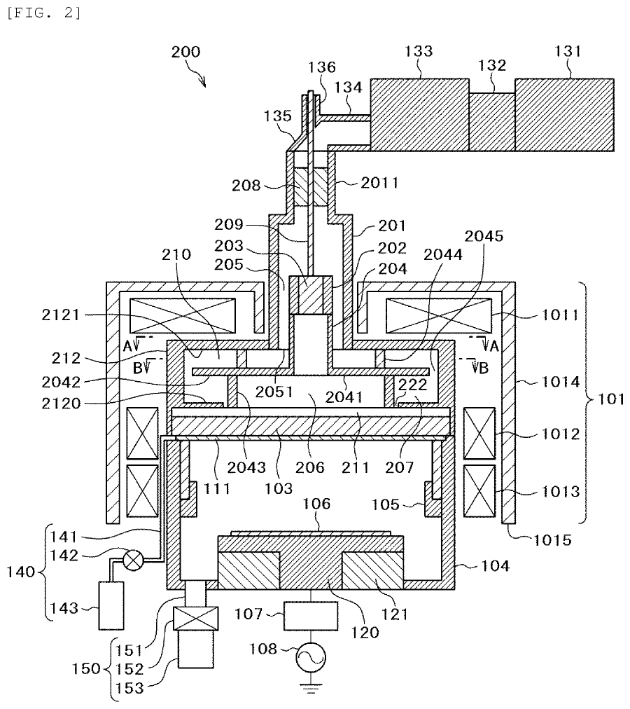

As an example of the plasma processing apparatus using the invention, a microwave plasma etching apparatus 200 will be described with reference to FIGS. 2 to 7.

The present inventors have investigated a method of controlling the density distribution of the generated plasma by adjusting the distribution of the microwave electromagnetic field in the processing chamber based on the etching apparatus 100 for explaining the principle of the invention which is shown in FIG. 1. As a result, a structure shown in FIG. 2 is obtained. The same parts as those of the etching apparatus 100 for explaining the principle of the invention which is shown in FIG. 1 are denoted by the same reference numerals. The descriptions about the same parts as those shown in FIG. 1 including the same reference numerals will be omitted, and the differences will be mainly described.

A configuration of the microwave plasma etching apparatus 200 shown in FIG. 2 is obtained by mainly changing internal structures of the circular waveguide 110 and the cavity portion 102 of the etching apparatus 100 for explaining the principle of the invention which is shown in FIG. 1.

The microwave plasma etching apparatus 200 is the same as the configuration of the etching apparatus 100 for explaining the principle of the invention which is shown in FIG. 1 in that the microwave plasma etching apparatus includes the microwave generating source 131, the isolator 132, and the automatic matching box 133, the electromagnet 101 including the upper coil 1011 and the lower coils 1012, 1013 and having the yoke 1014 provided on the outer periphery thereof is provided around the plasma processing chamber 104, the gas supply unit 140 and the exhaust system 150 are connected to the plasma processing chamber 104, and the RF power source 108 is connected to the substrate electrode 120 via the automatic matching box 107.

In the configuration of the microwave plasma etching apparatus 200 shown in FIG. 2, a first circular waveguide 201 is connected instead of the circular waveguide 110 of the etching apparatus 100 illustrated in FIG. 1, and a second circular waveguide 202 and a third circular waveguide 204 having a slightly enlarged radius on an output side thereof are disposed inside the first circular waveguide 201.

A circularly polarized wave generator 208 is built in a circular waveguide 2011 connected to the circular-rectangular converter 135. The first circular waveguide 201 having an enlarged diameter is connected to a lower part of the circular waveguide 2011 corresponding to an output end of the circularly polarized wave generator 208. The second circular waveguide 202 and the third circular waveguide 204 having a slightly enlarged diameter on the output side thereof are disposed inside the first circular waveguide 201. A dielectric 203 that serves as a mechanism for power division and adjustment is loaded inside the second circular waveguide 202.

The circular waveguide 2011, the first circular waveguide 201, the second circular waveguide 202, and the third circular waveguide 204 share a central axis.

A rod 209 made of a dielectric is connected to the dielectric 203. The rod 209 is disposed on the central axis of the first circular waveguide 201, and penetrates a center of the circularly polarized wave generator 208 to protrude to the outside from a guide portion 136 provided in the circular-rectangular converter 135.

An insertion amount of the dielectric 203 in the second circular waveguide 202 can be adjusted by inserting and removing (putting in and taking out) a portion protruding to the outside from the guide portion 136 from an outside of the circular-rectangular converter 135. The dielectric 203 is preferably a material that causes a small loss to the microwave and is also stable against a temperature change or the like, and quartz is used in the present embodiment.

A radius of the inside (an inner radius) of the second circular waveguide 202 is such that the microwave is cut off when the inside is filled with air and does not have the dielectric 203 loaded inside, and the microwave can be transmitted when the dielectric 203 is loaded inside. In the present embodiment, the radius is 30 mm. The dielectric 203 serves as a cutoff frequency control mechanism for the second circular waveguide 202.

In order to enable the transmission of the microwave when the internal medium is air, the third circular waveguide 204 needs to have a radius of the inside of 35.9 mm or more as described above, and has a radius of 40 mm in the present embodiment. It is also possible to load the dielectric into the third circular waveguide 204 to reduce the size.

A portion that is inside the first circular waveguide 201 and outside the third circular waveguide 204 operates as a coaxial waveguide 205. Generally, when the coaxial waveguide operates in a TEM mode, the transmission can be performed from a direct current whose frequency can be regarded as zero, and there is no cutoff, but when the coaxial waveguide operates in a higher-order TE mode, there is a cutoff. In the present embodiment, the coaxial waveguide 205 operates in a higher-order TE11 mode.

Unlike the circular waveguide, a cutoff frequency or the like cannot be calculated by a simple formula, but it is known that the cutoff frequency can be approximately calculated by a formula (Formula 3) in the TE11 mode of the coaxial waveguide.

$${k}_{c} \underline{≃} \frac{2}{a + b} \qquad [ Formula 3 ]$$

a: radius of inner conductor of coaxial waveguide (m)

b: radius of outer conductor of coaxial waveguide (m)

In consideration of the formula (Formula 3), the size is set such that the TE11 mode of the coaxial waveguide 205 does not cause cut off.

A flange portion 2041 is formed outside an output end side of the third circular waveguide 204, and a space formed by the flange portion 2041 and a circular tube 2043 acts as an inner antenna 206. In the present embodiment, a diameter of the circular tube 2043 is increased to open the microwave introduction window 103 side. Due to the cylindrical cavity type inner antenna 206, it is possible to generate the plasma having a convex distribution on the processing target substrate 106 in the plasma processing chamber 104.

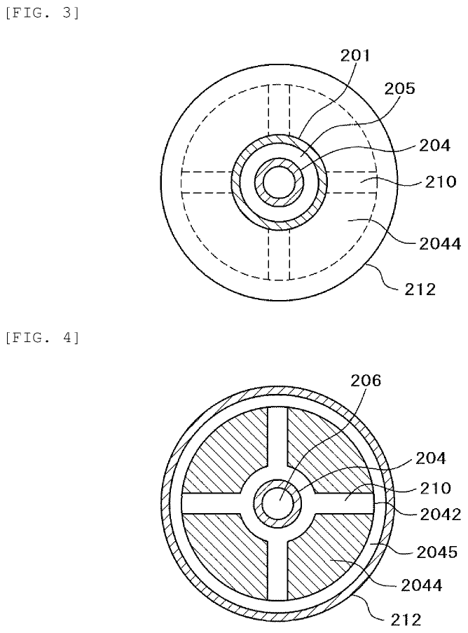

FIG. 3 shows a cross-sectional view taken along a line A-A in FIG. 2, and FIG. 4 shows a cross-sectional view taken along a line B-B. At an output end 2051 which is an outlet of the coaxial waveguide 205 to an inside of a cavity portion 212, a waveguide path 210 is formed by a waveguide path forming portion 2044 in a space surrounded by the cavity portion 212 and the flange portion 2041.

On the other hand, a space surrounded by the circular tube 2043, a flange portion 2042 and the cavity portion 212 outside the circular tube 2043, and a circular plate 2120 connected to the cavity portion 212 forms an outer antenna 207 that connects to the waveguide path 210 through a gap 2045 between the flange portion 2042 and the cavity portion 212.

The outer antenna 207 in the present embodiment forms a ring-shaped cavity resonator, but may have other structures as long as it is an antenna that can obtain an outer higher distribution on the processing target substrate 106. The outer antenna 207 having a ring-shaped cavity resonator structure uses a slot 2045 extended in the azimuth direction for connection with the waveguide path 210. Furthermore, in order to radiate the microwave to the plasma processing chamber 104, an annular slot formed by a gap 222 between the circular tube 2043 and the circular plate 2120 is used, but other structures such as a radial slot may be used as well.

A space 211 is provided between the inner antenna 206, the outer antenna 207, and the microwave introduction window 103 made of quartz. A height of the space 211 can be adjusted to mitigate microwave mismatching.

When the rod 209 is pulled up from the guide portion 136 side and the dielectric 203 is pulled out from the second circular waveguide 202, the second circular waveguide 202 is in a state of cutting off the microwave, and supply of the microwave to the inner antenna 206 is cut off. As a result, the microwave is not radiated from the inner antenna 206 to the plasma processing chamber 104, and is radiated from only the outer antenna 207 into the plasma processing chamber 104.

On the contrary, when the rod 209 is pushed down from the guide portion 136 side and the dielectric 203 is inserted into the second circular waveguide 202, the inside of the second circular waveguide 202 is loaded with the dielectric 203 and is in a state of enabling the transmission. In the state, the microwave is supplied from the third circular waveguide 204 to the inner antenna 206, and the microwave is supplied from both the inner antenna 206 and the outer antenna 207 into the plasma processing chamber 104.

In addition, a ratio of the microwave power supplied to the inner antenna 206 and the outer antenna 207 can be changed by adjusting a push-down amount or a pull-up amount of the rod 209 from the guide portion 136 side to change a position of the dielectric 203 attached to a tip portion of the rod 209. Since the distributions of the plasma generated by the inner antenna 206 and the outer antenna 207 are different from each other, the plasma distribution in the plasma processing chamber 104 can be controlled by changing the position of the dielectric 203 to adjust the ratio of the microwave power supplied to the inner antenna 206 and the outer antenna 207.

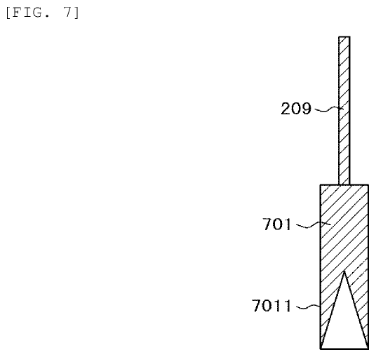

The dielectric 203 shown in FIG. 2 has a simple cylindrical shape, but a tip portion 6011 of a dielectric 601 may be sharpened as shown in a cross-sectional view in FIG. 6 (a dielectric 601), or a tip portion 7011 of a dielectric 701 may be provided with a tapered cavity portion as shown in a cross-sectional view in FIG. 7 (a dielectric 701).

When the tip portion 6011 or 7011 of the dielectric 601 or the dielectric 701 is loaded in the second circular waveguide 202, an equivalent relative permittivity changes slowly, so a change in microwave power transmittance with respect to the insertion amount of the dielectric 601 or 701 in the second circular waveguide 202 can be made slow. This has an effect of improving an accuracy of controlling the microwave power.

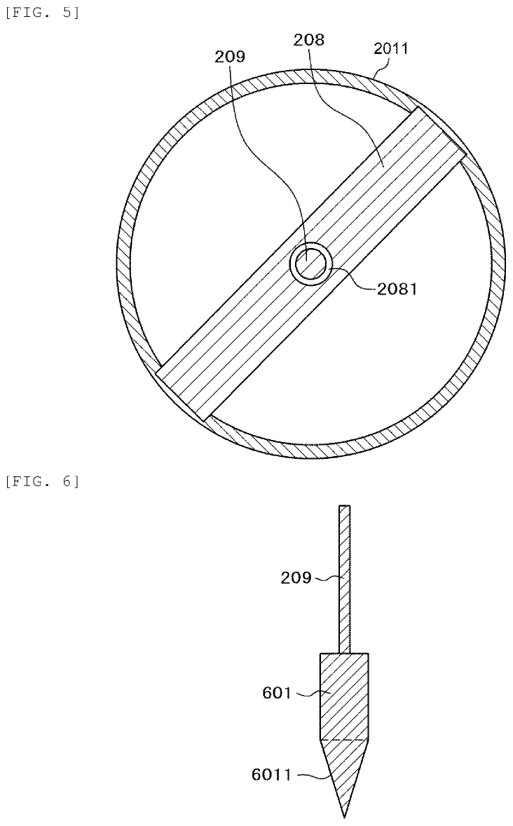

A structure shown in FIG. 5 is used as the circularly polarized wave generator 208. FIG. 5 is a cross-sectional view in a direction perpendicular to the central axis of the circular waveguide 2011. A known structure made of a dielectric plate disposed so as to be inclined at 45 degrees with respect to an electric field direction of the TE11 mode of the circular waveguide 2011 is used as the circularly polarized wave generator 208. Quartz is used as the dielectric.

As shown in the drawing, a hole 2081 through which the rod 209 passes is provided in the circularly polarized wave generator 208. A material of the rod 209 is also quartz, similar as that of the circularly polarized wave generator 208. In a dielectric plate having a hole, a relative permittivity of the hole portion decreases, so that an equivalent permittivity of the entire plate decreases and an efficiency for generating the circularly polarized wave decreases. However, by making the material of the rod 209 the same and making a diameter of the hole and a diameter of the rod substantially the same, it is possible to prevent a decrease in the equivalent permittivity and to prevent a decrease in the efficiency for generating the circularly polarized wave.

It is possible to monitor an etching state by measuring plasma emission during etching. For example, it is possible to measure the emission caused by a material to be etched or a reaction product on the processing target substrate during the plasma emission, and to monitor a progress state of etching based on a change thereof. In addition, it is possible to monitor a change in film thickness or the like based on a reflectance of light on a surface of the processing target substrate during etching. In order to utilize these techniques, it is necessary to use a translucent material to exchange the plasma emission or the like with the outside. A translucent material serving as the material of the rod 209 and the dielectric 203 can also serve as a port for monitoring.

As described above, the ratio of the microwave power supplied to the inner and outer antennas can be adjusted by positions of the rod 209 and the dielectric 203, whereby the distribution of the plasma generated in the processing chamber can be controlled. If it is not necessary to frequently adjust the ratio of the power supplied to the inner and outer antennas, the rod 209 may be omitted and the position of the dielectric 203 may be semi-fixed. Although the ease of controlling the plasma distribution is deteriorated, there are advantages that a drive mechanism such as the rod can be omitted and the structure can be simplified.

Generally, in a plasma processing apparatus that generates a plasma by using interaction between a microwave and a static magnetic field, there is a problem that a flat distribution is difficult to be obtained because the plasma density distribution on the processing target substrate tends to be convex especially under a condition that pressure in the processing chamber is high, but the flat distribution of the plasma density becomes easily obtained and the problem can be solved by adopting the plasma processing apparatus having the configuration as described in the present embodiment.

As described above, according to the present embodiment, the distribution of the density of the plasma generated in the processing chamber by each antenna can be adjusted by adjusting a magnitude of each microwave power radiated from each of the plurality of antennas. For example, when the inner antenna connected to the inner waveguide path and the outer antenna connected to the outer waveguide path are provided, and the inner antenna generates plasma having a center higher distribution and the outer antenna generates plasma having an outer higher distribution, a degree of the outer higher or center higher distribution of the plasma can be controlled by adjusting the microwave power supplied to the inner and outer antennas.

In addition, according to the present embodiment, since the distribution of the density of the plasma generated in the processing chamber can be adjusted, it is possible to prevent local scrape-off, due to the plasma, of a dielectric window portion that allows the microwave to pass through while keeping the vacuum processing chamber airtight, and it is possible to improve the uniformity of the plasma processing applied to the processing target substrate as compared with a case where the configuration as in the present embodiment is not adopted.

While the invention made by the inventor has been described in detail based on the embodiment, the invention is not limited to the above-described embodiment, and various modifications can be made without departing from the scope of the invention. For example, the above-mentioned embodiment has been described in detail for easy understanding of the invention, and is not necessarily limited to those having all the described configurations. In addition, a part of the configuration of each embodiment may be added, deleted, or replaced with another configuration.

### REFERENCE SIGN LIST

101 electromagnet
102 cavity portion
103 microwave introduction window
104 plasma processing chamber
105 ground electrode
106 processing target substrate
107 automatic matching box
108 RF power source
109 circularly polarized wave generator
110 circular waveguide
201 first circular waveguide
202 second circular waveguide
203 dielectric
204 third circular waveguide
205 coaxial waveguide
206 inner antenna
207 outer antenna
208 circularly polarized wave generator
209 rod
210 waveguide path
211 space
401 dielectric
501 dielectric

1. A plasma processing apparatus, comprising:
a processing chamber in which a sample is subjected to plasma processing;
a radio frequency power source configured to supply, via a waveguide path, radio frequency power of a microwave for generating plasma;
a magnetic field forming mechanism configured to form a magnetic field inside the processing chamber; and
a cutoff frequency control mechanism configured to control a cutoff frequency, wherein
the waveguide path includes a circular waveguide and a coaxial waveguide disposed outside the circular waveguide and disposed coaxially with the circular waveguide, and
the cutoff frequency control mechanism is configured to control a cutoff frequency of the circular waveguide.

2. The plasma processing apparatus according to claim 1, wherein
the cutoff frequency control mechanism includes a dielectric.

3. The plasma processing apparatus according to claim 2, wherein
the dielectric is disposed inside the circular waveguide,
the dielectric is configured to be inserted into and removed from the circular waveguide, so that the circular waveguide switches between cutting off the radio frequency power of the microwave and enabling transmission.

4. The plasma processing apparatus according to claim 2, wherein
the cutoff frequency control mechanism further includes an insertion amount control mechanism configured to control an insertion amount of the dielectric in the circular waveguide.

5. A plasma processing apparatus, comprising:
a processing chamber in which a sample is subjected to plasma processing;
a radio frequency power source configured to supply radio frequency power of a microwave for generating plasma via a waveguide path including a circular waveguide and a coaxial waveguide disposed coaxially outside the circular waveguide;
a magnetic field forming mechanism configured to form a magnetic field inside the processing chamber; and
a power ratio control mechanism configured to control a ratio of the radio frequency power supplied via the circular waveguide to the radio frequency power supplied via the coaxial waveguide to a desired ratio.

6. The plasma processing apparatus according to claim 5, wherein
the power ratio control mechanism includes a dielectric.

7. The plasma processing apparatus according to claim 6, wherein
the power ratio control mechanism further includes an insertion amount control mechanism configured to control an insertion amount of the dielectric in the circular waveguide.

8. A plasma processing apparatus, comprising:
a processing chamber in which a sample is subjected to plasma processing;
a radio frequency power source configured to supply, via a waveguide path, radio frequency power of a microwave for generating plasma;
a magnetic field forming mechanism configured to form a magnetic field inside the processing chamber; and
a cutoff frequency control mechanism configured to control a cutoff frequency, wherein
the waveguide path includes a first antenna and a second antenna disposed outside the first antenna and disposed coaxially with the first antenna.

9. The plasma processing apparatus according to claim 8, wherein
a first waveguide connected to the first antenna and a second waveguide connected to the second antenna are coaxially disposed.

10. The plasma processing apparatus according to claim 9, further comprising:
a power ratio control mechanism configured to control a ratio of the radio frequency power supplied to the first waveguide to the radio frequency power supplied to the second waveguide to a desired ratio.

11. The plasma processing apparatus according to claim 10, wherein
the power ratio control mechanism includes a dielectric.

12. The plasma processing apparatus according to claim 10, wherein
the power ratio control mechanism further includes an insertion amount control mechanism configured to control an insertion amount of the dielectric in the first waveguide.
